(19) United States
(12) Patent Application Publication
(10) Pub. No.: US 2011/0097528 A1
(43) Pub. Date: Apr. 28, 2011

(54) PACKAGING ELEMENT AND METHOD FOR ITS PRODUCTION

(75) Inventors: Markus Dippel, Glattfelden (CH); Wolfgang Lohwasser, Gailingen (DE); Manfred Hoffmann, Singen (DE); André Wisard, Huntwangen (CH)

(73) Assignee: ALCAN TECHNOLOGY & MANAGEMENT LTD., Neuhausen am Rheinfall (CH)

(21) Appl. No.: 12/673,045

(22) PCT Filed: Aug. 28, 2008
(86) PCT No.: PCT/EP08/07048

§ 371 Date: Feb. 11, 2010

(30) Foreign Application Priority Data
Sep. 3, 2007 (EP) 07405266.3

(51) Int. Cl. C08J 7/04; B32B 9/00; B32B 27/00; B65D 25/14; B05D 3/00; H05H 1/24; C08F 2/48; B29C 45/00; B29C 49/06; B29C 49/04; B29C 51/00; C23C 14/34; C23C 14/08

(52) U.S. Cl. 428/36.6; 428/335; 428/521; 428/500; 428/474.4; 428/480; 428/532; 428/447; 428/704; 428/689; 428/423.1; 428/524; 428/446; 428/688; 427/296; 427/578; 427/508; 264/328.1; 264/537; 264/539; 264/319; 204/192.16

(57) ABSTRACT

A packaging element formed from a plastic with an inorganic barrier layer with good penetration barrier effect against water vapour and gasses, where the packaging element is fitted with a coating generated in a vacuum with materials with the desired penetration barrier effect. The vacuum coating is over-lacquered to protect against abrasion and corrosion and to improve the mechanical stability.

The invention concerns a packaging element of moulded plastic with an inorganic barrier layer with good penetration barrier effect against water vapour and gasses, which packaging element has a coating produced under vacuum with materials with the said penetration barrier effect. The invention also includes a method suitable for production of the packaging element.

Foodstuffs have been packed in packaging of glass or aluminium for some time. Both materials offer one hundred percent protection against the penetration of gasses and water vapour. This means that no gasses can penetrate from the outside to the inside through the packaging walls, which protects the foodstuff from spoiling. At the same time, gasses cannot escape from the inside to the outside, which protects the product from aroma loss and desiccation.

Both packages are far from optimum from an ecological viewpoint and offer little scope for freedom in the design of the packaging form. Aluminium has the disadvantage that it cannot be used for production of transparent packaging, and glass packaging—as well as a high own weight—has the disadvantage that shattering or glass breakage must always be expected. Plastic packaging offers clear advantages here. As plastics usually however only have an inadequate gas barrier effect, such packaging must be fitted with an additional barrier layer. Various possibilities are known here:

One example is the thermoforming of multilayer flat foils which on the inside contain an oxygen barrier layer e.g. of EVOH. Transparent barrier packaging can be produced with this technology. However, this packaging has the disadvantage that because of the thermoforming process, its design freedom is very restricted. It is also known that on any sterilisation process (of the filled package), the gas barrier created by the EVOH temporarily collapses, which for a particular time allows the passage of oxygen through the wall of the packaging into the foodstuff. Similar restrictions apply to bottle-like containers with EVOH barrier layers which can be generated by a combination of injection and blow moulding or extrusion and blow moulding.

A further possibility is containers with integrated “in-mould label”, in the production of which a film with the desired barrier is inserted in an injection mould and then back-sprayed with plastic. Here too, however, the design freedom of the resulting containers is greatly restricted by the production process.

EP-B-1 048 746 also describes the production of containers with barrier effect by means of vacuum coating. The barrier packaging is produced by forming the container (injection moulding, thermoforming, blow moulding) and subsequent vacuum coating with a barrier layer of a suitable material. The packaging is sealed with a flexible barrier film as a cover film.

The resulting plastic barrier packaging is not yet optimum from the following aspects:
Often the pure vacuum coating alone does not achieve the desired barrier effect required for the conservation of the foodstuffs as specified by the customer.
The extremely thin vacuum coating is susceptible to mechanical abrasion and corrosion which e.g. can lead to loss of barrier effect during the handling necessary for automatic filling.
With regard to sterilisation applications of the packaging, most pure vacuum coatings do not have the required stability.
Due to the use of a flexible barrier film as a cover sealing film, the packaging cannot be resealed or only inadequately resealed after first opening.

The invention is therefore based on the object of refining a packaging element of the type described initially so that the packaging elements such as containers and cover lids do not have the disadvantages associated with the prior art.

The object of the invention is achieved in that the vacuum coating is overlacquered to protect against abrasion and corrosion and to improve the mechanical stability.

The packaging element can be moulded by thermoforming of flat film material, by injection moulding or a combination of injection and blow moulding or extrusion and blow moulding.

The vacuum coating can be applied with one of the methods described below:
Coating by means of plasma CVD with ceramic layers, preferably by PECVD (plasma-enhanced chemical vapour deposition) methods, with HMDSO (hexamethyldisiloxane) or TEOS (tetraethoxysilane) and particularly preferably with plasma pretreatment with HMDSO and oxygen, HMDSO and nitrogen, TEOS and oxygen, or TEOS and nitrogen.
Coating by means of DC, AC or RF sputter processes, with oxide or nitride or sulphide coating, preferably by means of DC sputtering as follows:
   In non-reactive mode starting from the oxide, sulphide or nitride target. Preferably DC sputtering of electrically conductive ceramic targets such as doped zinc oxide. Alternatively, the coating can be applied with RF sputtering of non-conductive ceramic targets.
   In reactive mode (e.g. tin oxide, titanium oxide) starting from the metal target with the addition of oxygen or nitrogen by means of AC or DC sputtering.
Coating by means of sputter processes with metallic layers of aluminium, steel, copper, tin, zinc, silver or mixtures thereof, for non-sterilisation applications preferably of aluminium, for sterilisation applications preferably of silver, steel, tin or zinc.

The over-lacquering of the vacuum-coated packaging part takes place for example by dip-coating, flood coating, cast lacquering, spray lacquering, pad printing or by ink jet. To reduce the layer thickness applied or for better distribution of the lacquer on the packaging element, the lacquering process can be followed by a centrifuging process.

Suitable lacquers are general lacquer systems based on natural binders, polycondensation resins, polyaddition resins, polymerisation resins or other binders e.g. sol-gel lacquers, silicates and silicones. The binders can also be cross-linked with different cross-linking resins e.g. isocyanates, melamine or urea resins, silanes or metal alkoxides.

In particular to improve the oxygen barrier properties, lacquers based on EVOH, PVDC, cationic or radical UV-hardening lacquers or sol-gel lacquers on the basis of alkoxysilanes and/or metal alkoxides and/or inorganic particles are preferred. These lacquers can also be cross-linked with various cross-linking resins such as isocyanates, melamine or urea resins, silanes or metal alkoxides.

Lacquers which, in addition to the oxygen barrier, also have sterilisation-resistant properties are again in particular lacquers based on EVOH, PVDC, cationic or radical UV-hardening lacquers or sol-gel lacquers based on alkoxysilanes and/or metal alkoxides and/or inorganic particles. These lacquers can be cross-linked with various cross-linking resins e.g. isocyanates, melamine or urea resins, silanes or metal alkoxides.

Particularly preferable are sol-gel lacquer systems and UV-hardening lacquers on the basis of acrylates or cationic cross-linking epoxides. Hardening takes place thermally or by radiation hardening. Hardening by UV light or electron beam is particularly preferred.

Packaging parts can for example take the form of a container to hold a filling and/or a lid for a container.

The coating and over-lacquering of the container and where applicable the lid can be performed on the inside or outside. The external coating for example allows the application of the barrier layer and the over-lacquer layer on the packaging which is already filled and closed.

A barrier packaging produced according to the invention with a container to hold a filling can for example be closed as follows:
by means of a flexible film with barrier effect which is sealed to the container, or
with a push-on, snap or folding lid or a screw cap which can comprise metal or plastic. In the case where the screw cap comprises plastic and therefore has an inadequate barrier effect, then as described above it can be fitted with a corresponding gas barrier by a combination of vacuum coating and over-lacquering.

Packaging elements according to the invention can also be lids for packaging made from glass, cardboard or other materials e.g. lids for glass bottles, screw caps for drinks cartons etc.

The method according to the invention allows the production of packaging elements from a larger number of raw materials. Above all, transparent plastics with good forming properties are suitable such as polyethylene (PE), polypropylene (PP), cycloolefin copolymers (COC), cycloolefin polymers (COP), polyvinylchloride (PVC), polyethylene terephthalate (PET), polyamide (PA) and laminates made of said materials.

Compostable and biologically degradable polymers and/or polymers based on renewable raw materials can also be used as starting materials to produce packaging elements.

Suitable compostable polymers are in particular polymers certified to EN 13432 and based on renewable or non-renewable raw materials, such as polymers based on starches (starch blends), PLA (polylactide), polyesters of the PHA type (polyhydroxyalkanoate) e.g. PHB (polyhydroxybutyrate), PHV (polyhydroxyvaleate), cellulose materials of chemically modified cellulose, further materials made from chemically modified cellulose, and specific synthetic polyesters made from crude oil or natural gas.

Polymers based on renewable raw materials are e.g. made from sugars, starches, vegetable oils or cellulose. Maize, potatoes, cereals, sugar cane and wood are the starting materials most often used.

Suitable polymers based on renewable raw materials are in particular specific polyesters e.g. based on PDO (bio-propandiol), specific polyamides e.g. made from ricin oil, and PE (polyethylene), polypropylene (PP) and PVC (polyvinylchloride), and based on bio-ethanol from e.g. sugar cane.

The vacuum coating with over-lacquering according to the invention allows the production of packaging elements of renewable raw materials with high barrier effect and with certified compostability according to the criteria of standard EN 13432.

If resistance to sterilisation conditions is required, preferably biopolymers are used such as PHA or polypropylene based on renewable raw materials.

In a particularly preferred embodiment of the method according to the invention, the production of packaging elements, the coating and the over-lacquering are performed in sequence.

The tables below show the influence of the barrier layer and various overlacquering systems on the oxygen barrier of packaging elements before and after sterilisation treatment.

Table 1 shows the barrier effect of packaging parts of polypropylene (PP) uncoated and coated with silver (Ag), steel (V2A) and tin (Sn), without overlacquer layer.

Table 2 shows the barrier effect of packaging parts of polypropylene (PP) coated with silver (Ag) and steel (V2A) with an over-lacquer layer of different lacquer systems.

Table 3 shows the barrier effect of packaging parts of polylactide (PLA) coated with silver (Ag) and steel (V2A) without over-lacquer layer.

TABLE 1
Oxygen barrier at 25° C. and 50% rH in cm³/
(m²-24 h-bar), effect of inorganic barrier layer

| Packaging | Before | After sterilisation at |
|---|---|---|
| material | sterilisation | 121° C. 30 min |
| PP500 uncoated | 500 | 500 |
| PP/Ag | 15 | 75 |
| PP/V2A | 30 | 370 |
| PP/Sn | 36 | 350 |

TABLE 2
Oxygen barrier at 25° C. and 50% rH in cm³/(m²-24 h-bar),
effect of additional over-lacquering

| Packaging | | After sterilisation at |
|---|---|---|
| material | Before sterilisation | 121° C. 30 min |
| PP/Ag/lacquer 1 | 0.5 | 0.98 |
| PP/Ag/lacquer 2 | 9.4 | 28 |
| PP/Ag/lacquer 3 | 1.1 | 2.3 |
| PP/V2A/lacquer 1 | 0.4 | 6.2 |
| PP/V2A/lacquer 2 | 31 | 210 |
| PP/V2A/lacquer 3 | 3.1 | 6.4 |

Lacquer 1 = 100% UV system (solvent-free) cationic hardening
Lacquer 2 = 100% UV system (solvent-free) radical hardening
Lacquer 3 = thermal hardening (with solvent) sol-gel system

TABLE 3
Oxygen barrier at 25° C. and 50% rH in cm³/
(m² 24 h bar), influence of inorganic barrier layer

| Packaging material | |
|---|---|
| PLA (1 mm) uncoated | 14.5 |
| PLA (1 mm)/Ag | 1.9 |

1. Packaging element of molded plastic comprising an inorganic barrier layer with good penetration barrier effect against water vapor and gasses, and fitted with a coating produced under vacuum with materials with the desired penetration barrier effect, wherein the vacuum coating is over-lacquered to protect against abrasion and corrosion and to improve the mechanical stability.

2. Packaging element according to claim 1, wherein the thickness of the over-lacquer layer is 1 to 30 μm.

3. Packaging element according to claim 1, wherein the packaging element is formed from polyethylene (PE), polypropylene (PP), cycloolefin copolymer (COC), cycloolefin polymer (COP), polyvinylchloride (PVC), polyethylene terephthalate (PET), polyamide (PA) or a laminate made from said materials.

4. Packaging element according to claim 1, wherein the packaging element is made from compostable polymers, in particular polymers based on renewable raw materials such as polymers based on starches (starch blends), PLA (polylactide), polyester of type PHA (polyhydroxyalkanoate), PHV (polyhydroxyvaleate), cellulose materials of chemically modified cellulose, further materials made from chemically modified cellulose, polymers based on renewable raw materials are in particular specific polyesters, specific polyamides, and PE (polyethylene), polypropylene (PP) and PVC (polyvinylchloride), based on bio-ethanol, and specific synthetic polyesters made from crude oil or natural gas, or laminates made from said materials.

5. Packaging element according to claim 1, wherein the packaging element is formed by thermoforming of flat film material, by injection molding or a combination of injection molding and blow molding (injection blowmolding) or extrusion and blow molding (extrusion blowmolding).

6. Packaging element according to claim 1, wherein the barrier layer comprises a ceramic layer generated by means of plasma CVD, preferably PECVD (plasma-enhanced chemical vapor deposition) with HMDSO (hexamethyldisiloxane) or TEOS (tetraethoxysilane), in particular with plasma pretreatment with HMDSO and oxygen, HMDSO and nitrogen, TEOS and oxygen, or TEOS and nitrogen.

7. Packaging element according to claim 1, wherein the barrier layer comprises a layer of oxide or nitride or sulphide generated by means of a sputtering method.

8. Packaging element according to claim 1, wherein the barrier layer comprises a metallic layer generated by means of sputtering process from aluminium, steel, copper, tin, zinc, silver or mixtures thereof, for non-sterilisation purposes preferably of aluminium, for sterilization purposes preferably of silver, steel, tin or zinc.

9. Packaging element according to claim 1, wherein the over-lacquer comprises a lacquer system based on natural binders, where applicable cross-linked with cross-linking resins, in particular isocyanates, melamine or urea resins, silanes or metal alkoxides, polycondensation resins, polyaddition resins, polymerization resins, in particular sol-gel lacquers, silicates and silicones.

10. Packaging element according to claim 1, wherein to improve the oxygen barrier properties and/or the sterilization-resistant properties, the lacquer comprises a lacquer based on EVOH, PVDC, a cationic or radical UV-hardening lacquer or a sol-gel lacquer based on alkoxysilanes and/or metal alkoxides and/or inorganic particles, where applicable cross-linked with cross-linking resins, in particular isocyanates, melamine or urea resins, silanes or metal alkoxides.

11. Packaging element according to claim 1, wherein the over-lacquer comprises an acrylate lacquer or sol-gel lacquer system hardened thermally or by radiation, in particular UV light or electron beams.

12. Packaging element according to claim 1 in the form of a container to hold a filling and/or a lid for a container.

13. Method for production of a packaging element with good penetration barrier effect against water vapor and gasses, wherein the packaging element is formed from a plastic and the penetration barrier effect against water vapor and gasses is generated after forming of the packaging element in the form of a coating under vacuum with materials with the desired penetration barrier effect, wherein the vacuum coating is overlacquered to protect against abrasion and corrosion and to improve the mechanical stability.

14. Method according to claim 13, wherein the container and where applicable the lid are formed from polyethylene (PE), polypropylene (PP), cycloolefin copolymer (COC), cycloolefin polymer (COP), polyvinylchloride (PVC), polyethylene terephthalate (PET), polyamide (PA) or a laminate made from said materials.

15. Method according to claim 13, wherein the container and where applicable the lid are made from compostable polymers, in particular polymers based on renewable raw materials such as polymers based on starches (starch blends), PLA (polylactide), polyester of type PHA (polyhydroxyalkanoate), PHV (polyhydroxyvaleate), cellulose materials of chemically modified cellulose, further materials made from chemically modified cellulose, polymers based on renewable raw materials are in particular specific polyesters, specific polyamides, and PE (polyethylene), polypropylene (PP) and PVC (polyvinylchloride), based on bio-ethanol, and specific synthetic polyesters made from crude oil or natural gas, or laminates made from said materials.

16. Method according to claim 14, wherein the container and where applicable the lid are formed by thermoforming of flat film material, by injection molding or a combination of injection molding and blow molding (injection blowmolding) or extrusion and blow molding (extrusion blowmolding).

17. Method according to claim 14, wherein the coating is performed by means of plasma CVD with ceramic layers, preferably by PECVD (plasma-enhanced chemical vapour deposition) with HMDSO (hexamethyldisiloxane) or TEOS (tetraethoxysilane), in particular with plasma pretreatment with HMDSO and oxygen, HMDSO and nitrogen, TEOS and oxygen, or TEOS and nitrogen.

18. Method according to claim 14, wherein the coating is performed by means of sputtering processes with layers of oxide or nitride or sulphide.

19. Method according to claim 14, wherein the coating is performed by means of sputtering processes with metallic layers of aluminium, steel, copper, tin, zinc, silver or mixtures thereof, for non-sterilization purposes preferably of aluminium, for sterilization purposes preferably of silver, steel, tin or zinc.

20. Method according to claim 14, wherein for over-lacquering, lacquer systems are used which are based on natural binders, where applicable cross-linked with cross-linking resins, in particular isocyanates, melamine or urea resins, silanes or metal alkoxides, polycondensation resins, polyaddition resins, polymerization resins, in particular sol-gel lacquers, silicates and silicones.

21. Method according to claim 14, wherein to improve the oxygen barrier properties, and/or the sterilization-resistant properties, for over-lacquering lacquers are used which are based on EVOH, PVDC, a cationic or radical UV-hardening lacquers or sol-gel lacquers based on alkoxysilanes and/or metal alkoxides and/or inorganic particles, where applicable cross-linked with cross-linking resins, in particular isocyanates, melamine or urea resins, silanes or metal alkoxides.

22. Method according to claim 14, wherein for overlacquering, acrylate lacquers and sol-gel lacquer systems are used and the hardening takes place thermally or by radiation, in particular UV light or electron beams.

23. Method according to claim 14, wherein the packaging part is a container to hold a filling and/or a lid for a container.

24. Method according to claim 14, wherein the production of the packaging part, the coating and the over-lacquering take place in sequence.
